(19) United States
(12) Patent Application Publication
(10) Pub. No.: US 2009/0114905 A1
(43) Pub. Date: May 7, 2009

(54) Organic electrical or electric component with increased lifetime

(75) Inventors: Clemens Ottermann, Hattersheim (DE); Jorn Pommerehne, Loerrach (DE); Klaus Bonrad, Weiterstadt (DE); Thomas Frank, Niederbrechen (DE); Marcus Bodesheim, Kronberg (DE)

Correspondence Address: DEMONT & BREYER, LLC, 100 COMMONS WAY, Ste. 250, HOLMDEL, NJ, 07733, US

(73) Assignee: Schott AG, Mainz (DE)

(21) Appl. No.: 11/722,498

(22) PCT Filed: Dec. 22, 2005
(86) PCT No.: PCT/EP2005/013832

§ 371 Date: Jun. 9, 2008

(30) Foreign Application Priority Data
Dec. 22, 2004 (DE) 10 2004 063 133.6

(51) Int. Cl. H01L 51/30; B05D 5/12; H01L 51/40

(52) U.S. Cl. 257/40; 427/58; 427/74; 438/99; 257/E51.024

(57) ABSTRACT

In order to increase the lifetime of organic electrical or electronic components, the invention provides an organic electrical or electronic component comprising at least one organic functional layer, wherein the component contains an (e-v) quenching substance for singlet oxygen.

The invention relates to organic electrical or electronic components; in particular, the invention relates to measures for increasing the lifetime of such elements.

Organic electronic components are being used to an increasing extent for a wide variety of electronic applications. Although they are generally significantly slower than elements based on inorganic semiconductors, the production of organic components is also significantly more cost-effective. Developments in this regard are aimed, inter alia, at printing complete circuits in a simple manner. Moreover, speed is not of primary importance in many applications. Examples in this respect are organic sensor technology and photovoltaics, organic transponder circuits for radio frequency identification (“RF-ID” labels).

However, organic compounds are generally less stable compared with the materials of inorganic semiconductor components. One problem with organic electronic components, therefore, is still their limited lifetime. The organic substances used as functional material in such components are in many cases reactive and degrade inter alia under the influence of oxygen. For many areas of application where reliability is very important, failures on account of aging of the components are still a significant impediment to further uptake of these products.

One possibility for increasing the lifetime of such elements consists in encapsulating the one or more organic layers in a gastight manner. In that case, too, oxygen can penetrate over the course of time, however. The oxygen can, however, also already be concomitantly incorporated or included in the device during production of the device. Thus, an inert gas used during production may be contaminated, or the materials used release oxygen over the course of time. Inter alia, indium tin oxide (ITO), which is used in many cases for electrode layers, is known to slowly emit oxygen which can degrade the functional materials of organic electronic or electrical components. Likewise, oxygen can be reversibly bonded in many metals and be emitted again. By way of example, silver and copper are known to be comparatively permeable to oxygen.

A further possibility for lengthening the lifetime, therefore, is to prevent oxygen present from reacting with the organic functional materials. By way of example, the oxygen can be chemically bonded with suitable substances, gettering materials, scavengers, reducing agents or desiccants, in particular for water.

Another possibility is to lower the reactivity of the oxygen. This can be achieved by quenching oxygen in the singlet state. One peculiarity of oxygen is that the first two electronically excited molecular states O₂(a¹Δ_{g}) and O₂(b¹Σ⁺_{g}) are singlet states and the ground state O₂(X³Σ⁻_{g}) is a triplet state. On account of selection rules, the O₂(a¹Δ_{g}) singlet state is metastable with a lifetime of typically a few microseconds through to a few hundred milliseconds, depending on the environment in which it is situated. Since most organic functional molecules have singlet multiplicity in the ground state, a reaction between these molecules and ground state oxygen is kinetically inhibited. On account of the singlet multiplicity and the energy content of O₂(a¹Δ_{g}) that is greater by 94.2 kJ/mol compared with the ground state, oxygen molecules in said singlet state are a considerably stronger oxidizing agent than oxygen in the triplet ground state, however.

In this case, it should supplementarily be pointed out that there is also a further singlet state of the oxygen molecule, given by O₂(b¹Σ⁺_{g}), which has an energy of 157 kJ/mol above the ground state. However, this state can undergo transition to O₂(a¹Δ_{g}) in a manner permitted by spin, such that the lifetime of the O₂(b¹Σ⁺_{g}) in solvents, or in the presence of collision partners, is at the very best scarcely more than 100 nanoseconds. Accordingly, this state is only of secondary importance for the deactivation of singlet oxygen.

JP 05-190282 A and JP 05-190283 disclose the use of singlet quenchers in OLEDs. By way of example, β-carotene or ethylene compounds, such as tetramethylethylene, are intended to serve as quenchers in those cases.

The non-radiative deactivation channel of singlet oxygen which occurs in the case of the quencher molecules described therein, in particular in the case of β-carotene, is the spin-permitted energy transfer (ET) to triplet states of the quencher substances functioning as acceptor molecules. The necessary condition for the deactivation is that the energy of the acceptor triplet lies below that of the singlet donor. This quenching or deactivation mechanism is also referred to as so-called “chemical quenching”.

Although β-carotene is known as an outstanding singlet oxygen quencher in biology and medicine, at the same time a number of disadvantages arise upon application in organic electronic components. By way of example, carotene is an intensive pigment which can correspondingly influence the optical properties. β-carotene and the molecules which are known from the prior art and which are used as quenchers of singlet oxygen typically also have a large molar mass. However, such large molecules can adversely influence or even prevent the electrical properties of the organic layer(s) of the components or the polymerization and/or deposition thereof during device production.

Tetramethylethylene is likewise known as a chemical quencher of singlet oxygen. This reaction is a non-radiative process in which the singlet oxygen attacks the double bond of the tetramethylethylene and a hydroperoxide arises as the reaction product.

The use of chemical quenchers such as e.g. tetramethylethylene may also be disadvantageous since the chemical quenchers can also initiate photochemical reactions and thus alter the organic layers. Moreover, during the chemical deactivation of singlet oxygen, reaction products or further consequential products can form which, for their part, are reactive and can then attack the functional molecules of the organic functional layer or, due to coloration or other physical properties, may adversely influence the function of the device in a manner that can only be predicted with difficulty.

Therefore, the invention is based on the object of increasing the lifetime of organic layers of components whilst avoiding or at least reducing the abovementioned disadvantages of known quenchers for OLEDs.

This object is already achieved in an extremely surprisingly simple manner by means of the subject matter of the independent claims. The subclaims relate to advantageous configurations and developments of the invention.

Accordingly, the invention provides an organic electrical or electronic component comprising at least one organic functional layer containing an (e-v) quenching substance for singlet oxygen. Particularly preferably, organic molecules are also used for the (e-v) quenching substance.

Such a component can be produced in a simple manner according to the invention by applying at least one organic functional layer on a substrate, wherein an (e-v) quenching substance is additionally introduced into the component.

In particular, in this case an (e-v) quenching substance can be introduced into the organic functional layer or in indirect or direct contact with the latter. The substrate used may be, inter alia, glass or else plastic, for instance for producing flexible components.

Within the meaning of this invention, an organic functional layer should be understood as a layer with an organic substance which is essential for the electrical, electronic or optoelectronic function of the component. Thus, an organic photovoltaic element, or an organic photocell as optoelectronic component in the simplest case typically comprises a functional organic layer with organic, photovoltaically effective molecules that is embedded between two electrode layers having different work functions. Further functional layers may also be present in addition to this layer and the electrode layers acting as anode and cathode. In the case of an organic transistor, as a further example as an organic functional layer an organic semiconducting layer is used between source, drain and gate electrodes.

Within the meaning of this invention, (e-v) quenching substance is understood as a substance with molecules which, on account of their functional group(s), are able to deactivate, or quench, singlet oxygen in collision-induced fashion by resonant energy transfer to vibronic states of the molecules. In this case, the electronic excitation energy in the collisions is converted into vibrational energy of the collision partner, that is to say the molecules of the (e-v) quenching substance. In this case, chemical deactivation occurs at most in accompanying fashion. The excitation energy of the singlet oxygen is correspondingly only converted into thermal energy. A reaction of the quenching substance which can lead to aggressive reaction products is avoided according to the invention. Moreover, the (e-v) quenching is essentially dependent on the functional groups of the molecules and scarcely on the overall construction thereof. This makes it possible also to enable the incorporation, without any problems, of abovementioned molecules having a low molar mass which do not disturb the electrical properties of the functional layer or disturb said properties at most to an insignificant extent. The energy transfer can take place in resonant fashion, that is to say particularly efficiently in the sense of with particularly high rate constants, particularly when the energy gaps of the vibrational states of the (e-v) quenching substance molecules are matched as well as possible to the energy gap between singlet and ground state oxygen. This means that it is advantageous if, during a resonant energy transfer, the electronic excitation energy of the singlet oxygen is converted as completely as possible into vibrational energy of the (e-v) quenching substance molecules. Any excess amounts of energy are called incorrect energy. Consequently, a particularly efficient, i.e. resonant quenching of singlet oxygen takes place if little incorrect energy occurs during the energy transfer.

The vibrational energy of the (e-v) quenching substance molecules is a molecular property. During the (e-v) quenching of singlet oxygen, principally the terminal molecular groups of an (e-v) quenching substance molecule take up the electronic energy of the singlet oxygen. Said terminal molecular groups are called terminal oscillators within the meaning of the invention.

Thus, it is advantageously possible to use an (e-v) quenching substance which contains molecules having at least one functional group with a terminal oscillator, wherein the terminal oscillator has a vibrational energy of the fundamental vibration or of a harmonic of the stretching vibration which is equal to the energy difference between the O₂(a¹Δ_{g}) and the O₂(X³Σ⁻_{g}) state of molecular oxygen or whose vibrational energy deviates from said energy difference by at most 37%, preferably by at most 10%, in particular with a vibrational quantum number n less than or equal to 3. In the region of these energetic deviations, the collision-induced energy transfer from the singlet oxygen with excitation of a stretching vibration is particularly probable, with the result that it is possible to achieve high rate constants for the resonant (e-v) deactivation.

The following reaction takes place during the deactivation with an (e-v) quenching substance:

O^{2 1}Δ_{g}(m=0)→O^{2 3}Σ⁻_{g} (m=0, 1, 2, 3, . . . ), and
X—Y (n=0)→X—Y (n=1, 2, 3 . . . ).

In this case, m denotes the vibrational quantum number of the stretching vibration of the oxygen molecule, n denotes the vibrational quantum number of the stretching vibration of the (e-v) quenching substance, and X-Y denotes a terminal oscillator with atoms X, Y, for example a hydroxyl group of a molecule. Here the most effective contribution to quenching is supplied in each case by the transition of the oxygen from m=0 to m=0. Within the meaning of the invention, therefore, an (e-v) quenching substance is understood particularly preferably as a quenching substance which contains at least one functional group with a terminal oscillator, wherein the terminal oscillator has a vibrational energy of the fundamental vibration or of a harmonic of the stretching vibration which is equal to the energy difference between the O₂(a¹Δ_{g}) (m=0) and the O₂(X³Σ⁻_{g}) (m=0) state of molecular oxygen or whose vibrational energy deviates from said energy difference by at most 37%, preferably at most 10%.

What are particularly suitable for deactivating singlet oxygen are (e-v) quenching substances which contain molecules having at least one hydroxyl group. Organic molecules are particularly preferably used as (e-v) quenching substance, water not being regarded as an organic molecule in this sense. Water is particularly suitable for deactivating singlet oxygen since water molecules are composed exclusively of OH groups. However, the use of water is only appropriate where the layers of the organic component including functional layers and electrode layers are not damaged by the water, with the result that water generally is not very suitable for organic electronic components. The hydroxyl group with an O—H bond as terminal oscillator is particularly well suited to resonant (e-v) quenching since the stretching vibrational energy matches well the excitation energy of the O₂(a¹Δ_{g}) state of the oxygen.

By way of example, the (e-v) quenching substance may, however, also contain molecules having at least one NH or NH₂ group or a C—H bond. These are somewhat less effective than OH groups, but a considerably accelerated quenching of the singlet oxygen can still also be achieved with NH or NH₂ groups, or with C—H bonds, in which an N—H or C—H bond in each case forms a terminal oscillator. In particular, it is also conceivable to use molecules which contain both N—H and O—H bonds.

An (e-v) quenching substance can protect the organic functional layer particularly effectively if the (e-v) quenching substance is present in said layer itself. In many cases it suffices here for the (e-v) quenching substance to be present in a concentration of at most 5 percent by weight of the active substance of the organic functional layer, preferably at most 1 percent by weight in the organic functional layer.

However, it may also be advantageous as an alternative or additional measure to accommodate the (e-v) quenching substance in a separate constituent of the component, and thus to prevent singlet oxygen that arises outside the organic functional layer from penetrating into the layer. This embodiment is possible since the rate constant of the diffusion of oxygen in the devices constituting the subject matter is so high that a deactivation of singlet oxygen in said layers can bring about an efficient protection of the functional layers.

It is advantageously possible to use molecules having a low molar mass which are readily mobile in the organic functional layer and/or do not disturb the electronic properties of the layer or disturb said properties only to a small extent.

Preferably, their molecular weight is less than 528 g/mol, preferably in particular less than 374 g/mol, and particularly preferably less than 178 g/mol. This means that (e-v) quenching substances are preferably used which have a limited size or a limited number of atoms in the molecule, such that the adverse influences on the organic functional layers, in particular on the organic functional layer, can be minimized as far as possible.

However, it is also possible to use substances having a large molar mass as quenching substances. Thus, in accordance with another embodiment of the invention, it is provided that the (e-v) quenching substance comprises a polymer having hydroxyl groups or NH or NH₂ groups. Said polymer may for example form a matrix for the molecules of the organic functional layer. It is also possible to use such a polymer as a constituent of the component which adjoins the organic functional layer with a surface, such that singlet oxygen can be neutralized at the interface formed in this case.

The (e-v) quenching substance is advantageously selected also on the basis of the layers of the component and their chemical and electrical properties. Examples of organic materials that may be contained as quenchers in an (e-v) quenching substance are:

a monohydric or polyhydric alcohol, cyclohexanol, a carbohydrate, a cellulose derivative, a starch derivative, a glycerol monooleate, an amino alcohol, a polyamine, a polyamide.

In the selection of the (e-v) quenching substance it can then be taken into account, for example, whether the substance is miscible with a solvent for producing the organic functional layer and/or possible further functional layers and/or whether the substance can react undesirably with one or more further materials of a layer of the organic electrical or electronic component.

As explained above, molecules having hydroxyl groups are particularly effective quenchers. The more hydroxyl groups there are, the better, accordingly, the quenching effect of the molecules. In accordance with one embodiment of the invention, therefore, an organic electrical or electronic component is provided in which the (e-v) quenching substance contains organic molecules having at least one hydroxyl group, where the ratio of total molar mass of said molecules to the molar mass of the hydroxyl groups is at most 5 to 1, preferably at most 3.5 to 1. By way of example, the ratio of total molar mass to molar mass of the one or more hydroxyl groups is only 1.88 in the case of the alcohols methanol (total molar mass Mₜₒₜ=32 g/mol, molar mass of hydroxyl groups M_{OH}=17 g/mol), 2.7 in the case of ethanol (Mₜₒₜ=46 g/mol, M_{OH}=17 g/mol), only 1.82 in the case of ethylene glycol (Mₜₒₜ=62 g/mol, M_{OH}=34 g/mol). Small values of this ratio of the molar masses can be achieved with carbohydrates, too. Thus, by way of example, a value of Mₜₒₜ/M_{OH}=3.17 results for cellulose. Sorbitol as (e-v) quencher even has a value of just Mₜₒₜ/M_{OH}=1.78.

One possibility for applying the at least one organic functional layer for producing the organic component to a substrate is coating from the liquid or gel phase, such as e.g. spin coating, dip or channel coating, or printing techniques, in particular inkjet printing, screen printing or flexographic printing. In this case, a solution in which the organic functional molecules and/or the starting substances thereof are dissolved is deposited on the substrate, or the substrate is withdrawn from the solution, with the result that a liquid film forms on the substrate surface. The organic functional layer is then produced from the liquid film by drying and/or reaction of starting substances, such as polymerization, for instance. In this embodiment of the invention, the (e-v) quenching substance can be introduced in a simple manner by dissolving the (e-v) quenching substance in a coating solution and applying it together with the active molecules or the starting materials thereof as a functional layer on the substrate.

A further possibility for applying organic functional layers on a substrate is to deposit them by vapor deposition. This method is suitable, in particular, for such active molecules of the functional layer which have low molar masses. In this case, in accordance with one development of this embodiment of the invention, the (e-v) quenching substance can be deposited by covaporization together with the active molecules of the organic functional layer in order to introduce the quenching substance into said layer.

In order to introduce the (e-v) quenching substance into the organic functional layer, the (e-v) quenching substance can also be present outside the organic functional layer and then diffuse into the latter.

For this purpose, the (e-v) quenching substance can advantageously also be applied in a separate layer before or after the application of the organic functional layer, that is to say as a support or covering of the organic functional layer. The quenching substance can then at least partially diffuse from the separate layer into the organic functional layer. In this case, the separate layer can also be resolved, for example.

Possibilities for this purpose are, inter alia:
application of a preferably thin layer comprising the (e-v) quenching substance—with or without a matrix—, for example by printing by means of inkjet technology, overlaying of this layer with a layer of a solution containing the organic material of the organic functional layer, dissolution of the (e-v) quenching substance layer by the solvent of the organic functional layer, mixing by diffusion of the materials in the liquid phase and subsequent formation of the organic functional layer with the (e-v) quenching substance by removal of the solvent and/or crosslinking. The reverse order is also possible.
application of a preferably thin layer of the (e-v) quenching substance with or without a matrix. Overlaying of this layer with a layer of a solution containing the material of the organic functional layer, but with solvents in which the (e-v) quenching substance is not soluble, i.e. formation of a separate film. This is followed by diffusion of the (e-v) quenching substance into the organic functional layer, also for example supported by suitable measures such as optical or thermal excitation or activation. The reverse order is also possible.
transfer of the (e-v) quenching substance into the organic functional layer by application of the (e-v) quenching substance as a layer to a carrier, “face-to-face” covering of the organic functional layer with the carrier, that is to say arrangement of carrier and functional layer in a position opposite each other with contact between carrier and layer or else without any contact. The liberation of the (e-v) quenching substance on the carrier can be effected by thermal and/or optical action, for example also locally, for instance by irradiation using a laser. Diffusion of the (e-v) quenching substance into the organic functional layer subsequently takes place. By this means, the quenching substance can also be deposited in patterned fashion in a simple manner.

In accordance with another embodiment of the invention, provision is made for encapsulating the organic functional layer in a covering, the (e-v) quenching substance being enclosed in the covering and then being present within the covering. In this case, the covering can, in particular, also form a cavity in which the (e-v) quenching substance is present. The (e-v) quenching substance enclosed in the cavity can then partially also diffuse into the organic functional layer.

It is likewise possible for the singlet oxygen arising in the organic functional layer to diffuse into the cavity and thus to the (e-v) quenching substance and to be deactivated there, such that in the entire device an equilibrium of ground state and singlet oxygen is established which is harmless for the device or at least reduces the quantity of singlet oxygen present in the device.

A further possibility for introducing (e-v) quenching substances into the device directly or by means of diffusion is incorporation into a patterned insulation or resistance layer between two electrode layers of the component, which layer serves for locally interrupting or attenuating the current flow.

Moreover, in accordance with another embodiment of the invention, a blocking layer with an (e-v) quenching substance can be applied, which protects the organic functional layer. This can additionally also act as a barrier in order, for instance, to prevent or at least slow down the penetration of further oxygen or else of moisture.

Further embodiments of the invention in which an (e-v) quenching substance is introduced into the component outside the organic functional layer provide for using a substrate which contains an (e-v) quenching substance or in the case of which a film with an (e-v) quenching substance is applied. In this case, too, the film or the substrate can neutralize singlet oxygen that diffuses into or out of the substrate or the film. For effective protection of the organic functional layer, it is possible in this case for the film or the substrate to be in contact with the at least one organic functional layer in order to reduce diffusion paths to a neutralization of the singlet oxygen.

In many cases organic components also have adhesive bonds, for example in order to connect an encapsulation to a substrate of the component. In this case, one development of the invention provides for an adhesive containing an (e-v) quenching substance to be used for the adhesive bonding of at least one part onto the substrate. Such a development affords the advantage, inter alia, that it is also possible to use (e-v) quenching substances which, if they were arranged within the functional layer, would adversely influence the properties of the organic functional layer.

In order to minimize the influence of the (e-v) quenching substance on the organic functional layer, it is furthermore advantageous if the HOMO and LUMO states of the molecules of the (e-v) quenching substance have a higher energy gap than the HOMO and LUMO states of the active molecules of the organic functional layer.

It is also possible to introduce an (e-v) quenching substance in the form of particles. The particles can be very small and consequently also comprise nanoparticles, in particular. Within the meaning of the invention, particles are understood to be not only solid particles but also liquid or gelatinous droplets which are dispersed or emulsified, for example. The particles can be composed of the (e-v) quenching substance themselves, or contain the latter, for example at their surface, or have OH groups at the surface.

In an advantageous manner, it is also possible to provide even further measures for protecting the organic electrical or electronic component against the effect of oxygen and other reactive substances. Further effective protection in this case is a gettering material for water and/or oxygen.

The invention is suitable for a multiplicity of applications. Thus, the organic electrical or electronic component may comprise at least one of the elements an organic transistor,

an organic diode,

an organic optoelectronic sensor,

an organic memory element, for example a PFRAM (polymer ferroelectric random access memory),

an organic RF-ID label.

In particular, it is also possible according to the invention to produce entire organic circuits, such as for an abovementioned identification label, for instance, using organic components according to the invention.

The invention is also very well suited to the production of organic photovoltaic or solar cells. In particular, the arising of singlet oxygen is fostered by sunlight, such that the use of (e-v) quenching substances according to the invention is advantageous precisely for the application as solar cell.

For producing solar cells or optoelectronic sensors, it is possible for example to apply an organic functional layer with a photovoltaically effective organic substance. By way of example, anthocyans are known as substances of this type.

For producing organic electronic components, in accordance with one development of the invention, in particular at least one organic semiconductor layer is applied. Here in particular polycyclic hydrocarbons have proved worthwhile, here preferably acenes, such as tetracene, pentacene or hexacene. Pentacene is a widespread material for organic thin-film transistors. However, these acenes are all highly sensitive to oxidation, so that the use of additional (e-v) quenching substances according to the invention is particularly advantageous here. Although the acenes themselves are known as quenchers for singlet oxygen, the deactivation mechanism does not take place via an electronic-vibronic energy transfer, but rather via a chemical deactivation which makes these substances precisely so sensitive to oxidation. By contrast, the (e-v) quenching substances used according to the invention do not react with the singlet oxygen.

The invention is explained in more detail below on the basis of exemplary embodiments and with reference to the drawings, in which case identical and similar elements are provided with identical reference symbols and the features of different exemplary embodiments can be combined with one another.

In the figures:

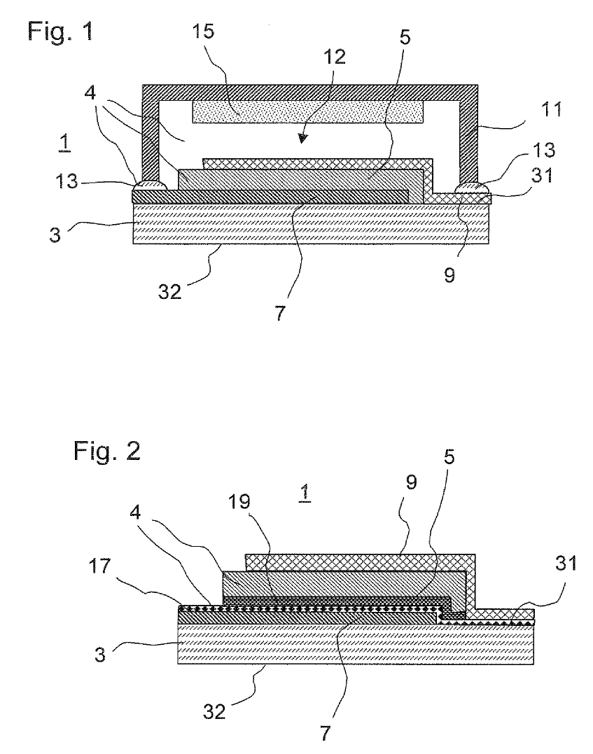

FIG. 1 shows a first exemplary embodiment of an organic electrical or electronic component according to the invention which is formed as an optoelectronic sensor,

FIG. 2 shows a further exemplary embodiment of an organic electrical or electronic component according to the invention which is formed as an optoelectronic sensor,

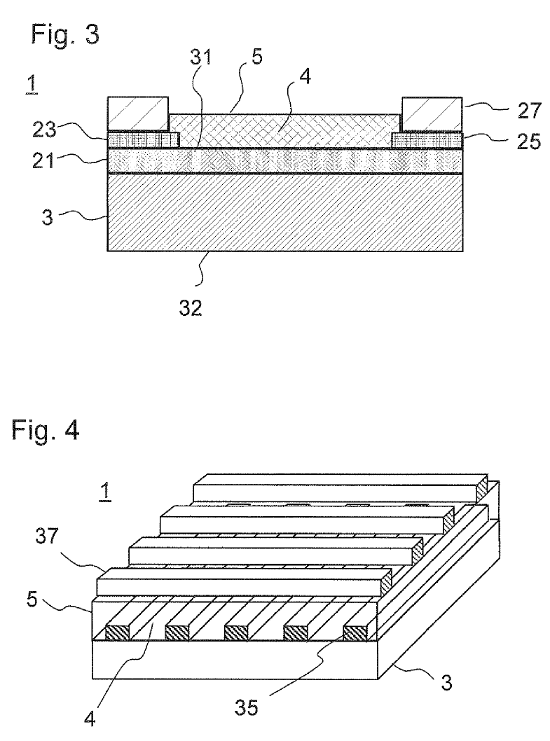

FIG. 3 shows an exemplary embodiment of a component according to the invention which is formed as a thin-film transistor,

FIG. 4 shows an exemplary embodiment of a component according to the invention comprising memory cells,

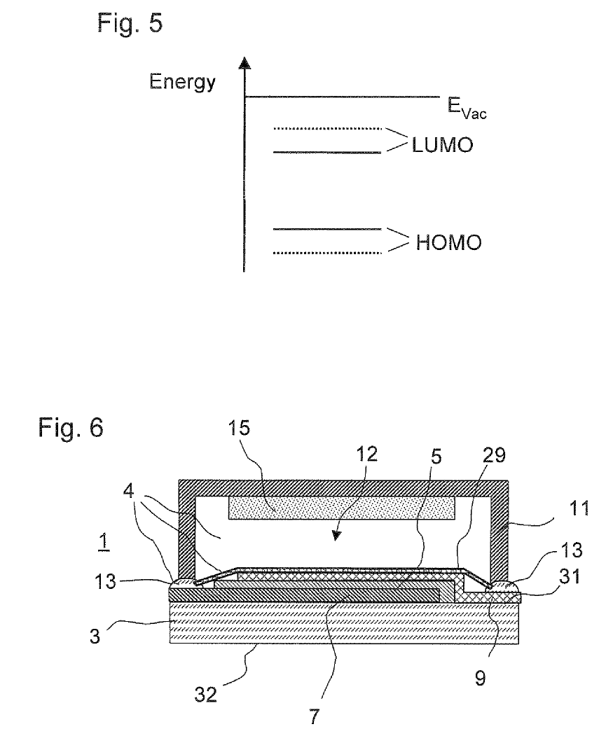

FIG. 5 shows a schematic state diagram with HOMO and LUMO states of the active molecules of the organic layer and the (e-v) quenching substance,

FIG. 6 shows a variant of the exemplary embodiment shown in FIG. 1 with a film containing the (e-v) quenching substance, and

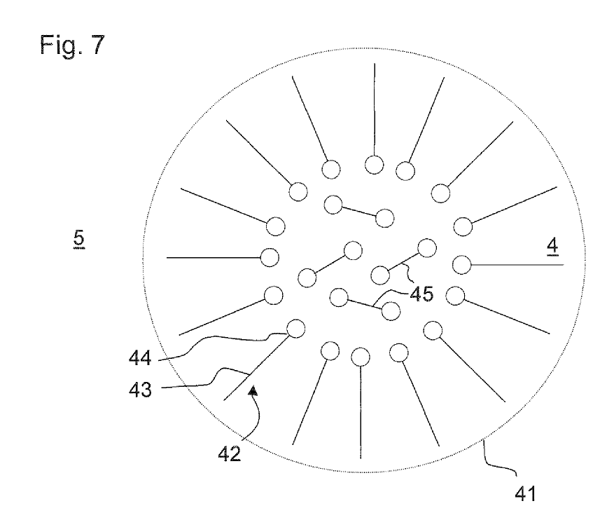

FIG. 7 shows a particle comprising an (e-v) quenching substance embedded into the organic functional layer.

FIG. 1 shows a first exemplary embodiment of an organic electrical or electronic component, which is designated as a whole by the reference symbol 1. Specifically, an optoelectronic sensor is illustrated in the case of the exemplary embodiment shown in FIG. 1.

The layer construction of the sensor as shown schematically in FIG. 1 comprises a layer sequence having an organic photovoltaic layer having an organic photovoltaically effective material arranged between two electrode layers of the layer sequence.

In addition, further functional layers can be provided between the electrode layers in order, inter alia, to increase the quantum efficiency. By way of example, it is possible to use a so-called hole transport layer in order to compensate for the different mobilities of generated holes and electrons.

The component 1 comprises a substrate 3—for example composed of glass or plastic—with sides 31, 32, a transparent electrode layer 7 being deposited on said substrate. By way of example, the conductive transparent indium tin oxide is appropriate as the transparent electrode layer 7. As organic functional layer 5, a layer having an organic photovoltaically effective substance is deposited onto the substrate's side 31 coated with the electrode layer 7.

The layer 5 may be a polymer layer, for example, which is applied by means of liquid coating. Equally, however, the organic functional layer 5 can also be applied by vapor deposition. As mentioned above, there may also be further functional layers present in the layer sequence between the electrode layers 7, 9. These are known to the person skilled in the art and are not illustrated in FIG. 1 for the sake of clarity.

A further electrode layer 9 is applied on the substrate's side 31 provided with first electrode layer 7 and organic functional layer 5. The electrode layer 9 is preferably a metal layer having a different electronic work function from that of the first electrode layer 7. It is favorable to choose for the electrode layer 9 a material having a work function that is lower than the work function of the first electrode layer 7. Suitable materials are, inter alia, aluminum, barium or calcium. Further materials are known to the person skilled in the art. However, the layer sequence can also be designed in inverse fashion, a transparent covering being provided on the substrate, through which covering the light to be detected can enter.

On account of the different work functions, electrons and holes generated in the functional layer 5 migrate to the electrodes, with the result that a voltage can be tapped off.

The suitable organic photovoltaically effective materials are typically oxygen-sensitive. The electrode layer 9, too, can likewise oxidize. In order to protect the sensitive layers 5, 9, in the exemplary embodiment shown in FIG. 1, a covering 11 is adhesively bonded to the substrate 3 with formation of adhesive joints or adhesive bonds 13. In this case, the covering 11 encloses a cavity 12. As a further protective measure for the layers 5, 9, a gettering material 15 for water and/or oxygen is additionally present within the cavity 12 at the covering 11. Calcium oxide, inter alia, is suitable as gettering material 15. Further covering methods and embodiments are known to the person skilled in the art.

According to the invention, an (e-v) quenching substance 4 for singlet oxygen is also additionally present in the organic component 1 formed as a photocell. The quenching substance 4 may be present in particular, as shown in FIG. 1, in the functional layer 5. One possibility for introduction into the layer 5 is, in the case of a liquid coating of the side 31 of the substrate 1, simply to concomitantly dissolve the (e-v) quenching substance 4 in the polymeric or dendrimeric solution to be applied and to apply it together with the other component or components of the layer. Another possibility is, in the case of a vapor-deposited layer 5, to deposit the (e-v) quenching substance 4 by covaporization together with the active molecules—that is to say for example photovoltaically effective molecules in the case of an organic photocell or solar cell—of the functional layer 5.

A further possibility for introducing the (e-v) quenching substance 4 into the functional layer 5, which can be provided as an alternative or in addition, is to introduce the (e-v) quenching substance 4 within the covering 11 encapsulating the functional organic layer 5. The quenching substance 4 is then present in the cavity 12 formed by the covering. If the molecules of the quenching substance 4 have a sufficiently low molar mass, then the molecules can also diffuse in sufficient quantity into the functional layer 5 whilst establishing an equilibrium vapor pressure.

The (e-v) quenching substance can also be applied in a separate layer before or after the application of the layer 5. The quenching substance 4 can then at least partially diffuse into the organic layer 5 from said separate layer. In this case, the separate layer can also be completely resolved.

Moreover, as illustrated in FIG. 1, the (e-v) quenching substance 4 can alternatively or additionally be present in the adhesive bond 13, for example by using an adhesive containing the quenching substance 4 when the covering 11 is adhesively bonded on.

FIG. 2 illustrates a further exemplary embodiment of an organic electrical or electronic component 1 according to the invention. The component 1 may have a covering 11 in the same way as the component shown in FIG. 1. However, the covering or other encapsulations are omitted in FIG. 2 for the sake of clarity.

In this exemplary embodiment, a conductive blocking layer 17 for the functional organic layer 5 is additionally applied on the conductive transparent electrode layer 7. Moreover, a hole transport layer 19 is also present as a further functional layer between the electrode layers 7 and 9 in order to increase the quantum efficiency.

Indium tin oxide as transparent conductive electrode layer 7 emits oxygen over the course of time. In this case, the blocking layer serves as an oxygen barrier in order to prevent or slow down the penetration of oxygen into the functional layers 5 and 19. In order to improve the protection of the organic functional layer 5 and/or of the hole transport layer 19, this exemplary embodiment additionally provides for the blocking layer 17 to contain an (e-v) quenching substance. In addition, in this case as well, as shown in FIG. 2, it is possible for an (e-v) quenching substance also to be introduced in the organic functional layer 5.

The exemplary embodiments illustrated with reference to FIG. 1 or 2 can be used for example also as solar cells or, using a plurality of sensor elements on a substrate 3, also as an image sensor.

FIG. 3 shows an exemplary embodiment of an organic component 1 formed as an organic thin-film transistor.

A doped silicon substrate 3 is used in this exemplary embodiment. The substrate may be p-doped, for example. In this case, the surface of the side 31 of the substrate 3 is oxidized, such that a silicon oxide insulation layer 21 is formed. Source and drain electrodes 23, 25 are applied on said layer 21. Said electrodes may be produced for example by photolithographic patterning of a gold layer. A further insulation layer 27 may also be applied on the electrodes 23, in order to insulate adjacent transistor elements on the substrate 3 from one another. Furthermore, an organic functional layer 5 is applied on the side 31, which is in contact with the electrodes 23, 25 and insulated by means of the insulation layer 21 from the for example p-conducting silicon—functioning as a gate—of the substrate 3.

Inter alia, pentacene and/or thiophenes such as quaterthiophene or sexithiophene are suitable as material for the organic functional layer 5, or as active molecules of the layer 5. In this exemplary embodiment of the invention, too, the (e-v) quenching substance is situated in the layer 5 in a mixture with the active molecules. As also in the case of the exemplary embodiments explained with reference to FIGS. 1 and 2, in this case the (e-v) quenching substance is preferably present in a concentration of at most 5 percent by weight, particularly preferably of at most 1 percent by weight, of the active substance in the layer 5.

If an organic ferroelectric polymer is used in the organic functional layer 5, then the exemplary embodiment illustrated in FIG. 3 can also serve as an organic RAM memory cell.

Instead of a silicon substrate, a polymer or plastic substrate can also be used in the example illustrated in FIG. 3. The coating with the organic functional layers can then advantageously be carried out, inter alia, for mass production in a roll-on-roll coating process. The layer construction of components for circuits that can be produced in this way is known to the person skilled in the art. By way of example, electronic circuits or RF-ID labels can be produced by such a method.

FIG. 4 shows an exemplary embodiment of an organic component 1 according to the invention with a memory cell arrangement having PFRAM cells. For this purpose, metal lines 35 are arranged on a substrate 3. Said metal lines can be applied by vapor deposition or sputtering, for example, using thin-film technology. The substrate 1 is additionally coated with an organic functional layer 5 on the side with the metal lines 35. Further metal lines 37 are applied on said layer 5, said further metal lines running transversely with respect to the metal lines 35 and being separated from the latter by the layer 5. Here, too, the organic functional layer 5 may once again be for example a ferroelectric polymer layer. By applying a voltage between a respective one of the metal lines 35 and 37, it is possible to polarize the ferroelectric material in the region between the lines in order to impress an item of bit information. In this case, too, according to the invention an (e-v) quenching substance 4 is contained in the layer 5 in order to protect the polymer molecules of the layer 5 against reaction with singlet oxygen.

The selection of suitable (e-v) quenching substances is advantageously also made on the basis of the gaps between the electronic states of the active molecules and the molecules of the (e-v) quenching substance. FIG. 5 shows a schematic state diagram for illustration purposes. The solid lines respectively represent the highest occupied molecular orbital (“HOMO”) and the lowest unoccupied molecular orbital (“LUMO”) of the active molecules. The broken lines identify the HOMO and LUMO states of the molecules of the (e-v) quenching substance. In order to minimize the influence on the electrical and/or electro-optical properties of the active layer, the (e-v) quenching substance is selected such that, as shown in the diagram, the HOMO and LUMO states of the molecules of the (e-v) quenching substance have a higher energy gap than the HOMO and LUMO states of the active molecules of the organic functional layer.

If the LUMO states of the molecules of the (e-v) quenching substance are too low, they can act as trap states for electrons which flow through the layer. Equally, HOMO states of the molecules of the (e-v) quenching substance that are at excessively high energy can act as traps for holes. In both cases, for example, the current flow through the layer can be adversely influenced. Moreover, in a functional organic layer 5 such as is present in the exemplary embodiments of FIGS. 1 and 2, the quantum efficiency can be lowered as a result of this trap effect.

In order to achieve efficient quenching of singlet oxygen, the (e-v) quenching substance is furthermore preferably chosen such that it contains molecules having at least one functional group with a terminal oscillator whose vibrational energy of the fundamental vibration or of a harmonic of the stretching vibration is equal to the energy difference between the O₂(a¹Δg) and the O₂(X³Σ⁻_{g}) state of molecular oxygen or whose vibrational energy deviates from said energy difference by at most 37%, preferably at most 10%.

This condition is met in particular by molecules containing at least one hydroxyl group. In this respect, furthermore, molecules having at least one NH or NH₂ group, or C—H bonds, are also suitable, but an N—H bond or C—H bond exhibits a lower deactivation efficiency in comparison with an O—H bond as terminal oscillator. The energies of the stretching vibration are E=2960 cm⁻¹ for a C—H bond, E=3355 cm⁻¹ for an N—H bond and 3755 cm⁻¹ for an O—H bond.

Suitable substances comprising such terminal O—H, C—H or N—H oscillators are, inter alia:

monohydric or polyhydric alcohols, for example ethanol, ethylene glycol, glycerol, cyclohexanol;

carbohydrates, for example mono-, di- and trisaccharides;

cellulose derivatives and/or starch derivatives, for example cellophane;

glycerol monooleates, for example glycerol monooleate, glycerol monoricinoleate, glycerol monostearate;

amino alcohols;

polyamines;

polyamides.

Cellulose derivatives, starch derivatives, polyamines and polyamides are additionally examples of an (e-v) quenching substance comprising a polymer having hydroxyl groups or NH or NH₂ groups. Such (e-v) quenching substances can be used for example in the form of a film or a substrate for the organic functional layer in the organic component. Thus, by way of example, the substrate 3 of the exemplary embodiments shown in FIG. 1 or 2 may comprise such a polymer.

FIG. 6 shows an exemplary embodiment with a film comprising a polymeric (e-v) quenching substance. This exemplary embodiment is a variant of the OLED illustrated in FIG. 1. The layers 5, 7, 9 of this organic component—here once again an optoelectronic sensor or a solar cell like the examples shown in FIGS. 1 and 2—are covered with a film 29 composed of polymeric (e-v) quenching substance arranged with the covering 11. In this case, the film 29 may be fixed with the adhesive bonds 13 for example as shown in FIG. 6. Inter alia, polyimide, polyamide or a starch or cellulose derivative, such as cellophane, for instance, may be used as (e-v) quenching substance 4 for the film. In addition, there may also be (e-v) quenching substance in the adhesive bond 13 and/or the cavity.

Unlike the illustration in FIG. 6, the organic component can also be constructed in such a way that the film 29 or the substrate with the (e-v) quenching substance is in contact with the organic functional layer 5.

It is also possible to use an (e-v) quenching substance in the form of particles. FIG. 7 shows an example of such an (e-v) quenching substance in particle form. The (e-v) quenching substance 4 of this exemplary embodiment comprises nanoparticles 41 embedded into the organic functional layer 5. The nanoparticles 41 comprise molecules 42 having a nonpolar end 43 symbolized by a line and one or more hydroxyl groups—symbolized by a circle—at the other end of the molecule 42. Examples of such molecules are, inter alia, monohydric alcohols such as ethanol, propanol or hexanol.

Hydroxyl groups increase the polarity of the molecule 42, whereby generally the solubility in an organic, nonpolar environment deteriorates. On the other hand, hydroxyl groups are outstandingly suitable as terminal oscillators for deactivating singlet oxygen, or converting it into the triplet ground state.

In the form of particles as shown by way of example in FIG. 7, it is possible, then, also to embed molecules having poor solubility into an organic functional layer. In this case, the nonpolar radicals 43 of the molecules 42 in the particle face outward, such that the polar OH groups lie internally in the particles 41. In this way, it is possible to embed even further molecules 45 of the (e-v) quenching substance internally in the particles 41, which molecules in isolated fashion on account of the high number of polar OH groups are only poorly soluble or not soluble at all in the active organic layer 5.

In this exemplary embodiment, the singlet oxygen is primarily deactivated during the diffusion through the nanoparticles 41 in collision-induced fashion.

It is apparent to the person skilled in the art that the invention is not restricted to the exemplary embodiments described above, but rather can be varied in diverse ways. In particular, the features of the individual exemplary embodiments can also be combined with one another.

### LIST OF REFERENCE SYMBOLS

1 Organic component
3 Substrate
4 (e-v) quenching substance
5 Organic functional layer
7 Conductive transparent electrode layer
9 Electrode layer
11 Covering
12 Cavity
13 Adhesive bond
15 Gettering material
17 Blocking layer
19 Hole transport layer
21 SiO₂ insulation layer
23, 25 Electrodes
27 Insulation layer
29 Polymer film
31, 32 Side of 3
35, 37 Metal lines
41 Nanoparticles
42, 45 Molecules of 4, 41
43 Nonpolar end of 42
44 Hydroxyl group

1. An organic electrical or electronic component comprising at least one organic functional layer, featuring an (e-v) quenching substance for singlet oxygen, said quenching substance containing a monohydric or polyhydric alcohol.

2. The organic electrical or electronic component as claimed in claim 1, wherein the molecular weight of the (e-v) quenching substance is less than 528 g/mol.

3. The organic electrical or electronic component as claimed in claim 1, wherein the (e-v) quenching substance contains molecules having at least one functional group with a terminal oscillator having a vibrational energy of the fundamental vibration or of a harmonic of the stretching vibration which is equal to the energy difference between the O₂(a¹Δ_{g}) and the O₂(X³Σ⁻_{g}) state of molecular oxygen or whose vibrational energy deviates from said energy difference by at most 37.

4. The organic electrical or electronic component as claimed in claim 1, wherein the (e-v) quenching substance contains molecules having at least one functional group with a terminal oscillator having a vibrational energy of the fundamental vibration or of a harmonic of the stretching vibration where n≦3 which is equal to the energy difference between the O₂(a¹Δ_{g}) and O₂(X³Σ⁻_{g}) state of molecular oxygen or whose vibrational energy deviates from said energy difference by at most 37%.

5-8. (canceled)

9. The organic electrical or electronic component as claimed in claim 1, wherein the (e-v) quenching substance is present in the organic functional layer.

10. (canceled)

11. The organic electrical or electronic component as claimed in claim 1, featuring a blocking layer with an (e-v) quenching substance.

12-13. (canceled)

14. The organic electrical or electronic component as claimed in claim 1, wherein the HOMO and LUMO states of the molecules of the (e-v) quenching substance have a higher energy gap than the HOMO and LUMO states of the active molecules of the organic functional layer.

15-16. (canceled)

17. The organic electrical or electronic component as claimed in claim 1, wherein the (e-v) quenching substance is present in a concentration of at most 5 percent by weight of the active substance of the organic functional layer in the organic functional layer.

18. (canceled)

19. The organic electrical or electronic component as claimed in claim 1, wherein the (e-v) quenching substance contains organic molecules having at least one hydroxyl group, where the ratio of total molar mass of said molecules to the molar mass of the hydroxyl groups is at most 5 to 1.

20. (canceled)

21. The organic electrical or electronic component as claimed in claim 1, wherein the component is a solar cell.

22. An organic circuit, comprising at least one organic component as claimed in claim 1.

23. A method for producing an organic electrical or electronic component, the method comprising:
applying at least one organic functional layer on a substrate; and
additionally introducing an (e-v) quenching substance into the component, said quenching substance containing a monohydric or polyhydric alcohol.

24. The method as claimed in claim 23, in which at least one organic functional layer of the component is applied on a substrate, wherein an (e-v) quenching substance is introduced into the functional layer or in indirect or direct contact with the functional layer.

25. (canceled)

26. The method as claimed in claim 24, wherein the (e-v) quenching substance is dissolved in a coating solution and applied together with the active functional molecules or the starting materials thereof as an organic functional layer on the substrate.

27-28. (canceled)

29. The method as claimed in claim 23, in which the organic functional layer is encapsulated in a covering, wherein the (e-v) quenching substance is enclosed in the covering.

30. The method as claimed in claim 23, wherein a blocking layer is applied, which contains an (e-v) quenching substance.

31-32. (canceled)

33. The method as claimed in claim 23, wherein the (e-v) quenching substance diffuses into the at least one organic functional layer.

34-38. (canceled)

39. The method as claimed in claim 23, wherein an organic functional layer with a photovoltaically effective organic substance is applied.

40. The method as claimed in claim 23, wherein an organic semiconductor layer is applied.

41. A method for producing an organic electric or electronic component, the method comprising utilizing, in the organic electrical or electronic component, an (e-v) quenching substance comprising monohydric or polyhydric alcohol, the quenching substance having a molecular weight of less than 528 g/mol.
